(19) United States
(12) Patent Application Publication
(10) Pub. No.: US 2026/0190230 A1
(43) Pub. Date: Jul. 2, 2026

(54) CIRCUIT MODULE AND SOLDERED CIRCUIT MODULE

(71) Applicant: Murata Manufacturing Co., Ltd., Nagaokakyo-shi (JP)

(72) Inventors: Junichi SAITO, Nagaokakyo-shi (JP); Takamitsu NAKAMURA, Nagaokakyo-shi (JP)

(73) Assignee: Murata Manufacturing Co., Ltd., Nagaokakyo-shi (JP)

(21) Appl. No.: 19/547,739

(22) Filed: Feb. 24, 2026

Related U.S. Application Data
(63) Continuation of application No. PCT/JP2024/033705, filed on Sep. 20, 2024.

(30) Foreign Application Priority Data
Dec. 5, 2023 (JP) 2023-205454

(51) Int. Cl. H05K 1/11; H05K 1/185

(52) U.S. Cl. CPC H05K 1/116; H05K 1/185; H05K 2201/0338; H05K 2201/09609; H05K 2201/09618; H05K 2201/10522

(57) ABSTRACT

A circuit module includes a substrate having a first main surface and a second main surface, a resin layer disposed on the first main surface, and a connection terminal extending through the resin layer in a thickness direction of the resin layer. The connection terminal includes a first end surface adjacent to the substrate, a second end surface opposite to the first end surface, and a side surface extending therebetween. The second end surface is exposed from the resin layer. The resin layer includes a recess that extends toward the first main surface and surrounds the second end surface. A portion of the side surface is exposed from the resin layer within the recess. A solder wettability improving layer is disposed on the second end surface of the connection terminal and on the portion of the side surface of the connection terminal exposed within the recess.

### CROSS-REFERENCE TO RELATED APPLICATIONS

The present application is a continuation of International Application No. PCT/JP 2024/033705, filed on Sep. 20, 2024, which claims priority to Japanese Patent Application No. 2023-205454, filed on Dec. 5, 2023, the entire contents of both are incorporated herein by reference.

### TECHNICAL FIELD

The present disclosure relates to circuit modules and soldered circuit modules.

### BACKGROUND ART

Patent Literature 1 discloses a radio-frequency module including: a module substrate having a first main surface and a second main surface, the first main surface and the second main surface being on opposite sides of the module substrate; a resin member that covers the second main surface; and a plurality of external connection terminals that are spaced apart from each other on the second main surface and that penetrate through the resin member from the second main surface; wherein the plurality of external connection terminals include a first external connection terminal, and the resin member includes a first recess that is recessed toward the second main surface and formed in at least part of a region of a surface of the resin member that surrounds a leading end part of the first external connection terminal.

### CITATION LIST

### Patent Literature

Patent Literature 1: JP 2021-197611 A

### SUMMARY

The circuit module of the present disclosure includes: a substrate having a first main surface and a second main surface; a resin layer disposed on the first main surface of the substrate; and a connection terminal extending through the resin layer in a thickness direction of the resin layer. The connection terminal includes: a first end surface adjacent to the substrate; a second end surface opposite to the first end surface; and a side surface extending between the first and second end surfaces. The second end surface is exposed from the resin layer. The resin layer includes a recess that extends toward the first main surface of the substrate and surrounds the second end surface of the connection terminal. A portion of the side surface of the connection terminal is exposed from the resin layer within the recess. A solder wettability improving layer is disposed on the second end surface of the connection terminal and on the portion of the side surface of the connection terminal exposed within the recess.

The soldered circuit module of the present disclosure includes: a substrate having a first main surface and a second main surface; a resin layer disposed on the first main surface of the substrate; a connection terminal extending through the resin layer in a thickness direction of the resin layer; and a solder bump bonded to the connection terminal via an intermetallic compound layer. The connection terminal includes a first end surface adjacent to the substrate, a second end surface opposite to the first end surface, and a side surface extending between the first and second end surfaces. The second end surface is exposed from the resin layer. The resin layer includes a recess that extends toward the first main surface of the substrate and surrounds the second end surface of the connection terminal. A portion of the side surface of the connection terminal is exposed from the resin layer within the recess. The solder bump covers the second end surface of the connection terminal and at least part of the portion of the side surface of the connection terminal exposed within the recess. The intermetallic compound layer is between the connection terminal and the solder bump and covers the second end surface of the connection terminal and at least part of the portion of the side surface of the connection terminal exposed within the recess.

### BRIEF DESCRIPTION OF DRAWINGS

FIG. 1 is a schematic cross-sectional view of an example circuit module of a first embodiment.

FIG. 2 is a plan view of the circuit module of the first embodiment, as seen from the surface provided with a resin layer and connection terminals.

FIG. 3 is an enlarged schematic view showing the structure around a connection terminal in the circuit module of the first embodiment.

FIG. 4 is a schematic view showing a state where a solder bump is bonded to the connection terminal shown in FIG. 3.

FIG. 5 is a schematic view of an example laser-irradiation trace on a connection terminal.

FIG. 6 is a schematic view showing another example laser-irradiation trace on a connection terminal.

FIG. 7 is an enlarged schematic view showing the structure around a connection terminal in a circuit module of a second embodiment.

FIG. 8 is an enlarged schematic view showing the structure around a connection terminal in a circuit module of a third embodiment.

FIG. 9 is an enlarged schematic view showing the structure around a connection terminal in a circuit module of a fourth embodiment.

FIG. 10 is an enlarged schematic view showing the structure around a connection terminal in a circuit module in a fifth embodiment.

FIG. 11 is a schematic cross-sectional view of an example soldered circuit module of the first embodiment.

FIG. 12 is an enlarged schematic view showing the structure around a connection terminal in the soldered circuit module of the first embodiment.

FIG. 13 is an enlarged schematic view showing the structure around a connection terminal in a soldered circuit module of the second embodiment.

FIG. 14 is an enlarged schematic view showing the structure around a connection terminal in a soldered circuit module of the third embodiment.

FIG. 15 is an enlarged schematic view showing the structure around a connection terminal in a soldered circuit module of the fourth embodiment.

FIG. 16 is an enlarged schematic view showing the structure around a connection terminal in a soldered circuit module of the fifth embodiment.

FIG. 17 is a schematic process diagram showing an example step of producing a soldered circuit module of the present disclosure.

FIG. 18 is a schematic process diagram showing an example step of producing a soldered circuit module of the present disclosure.

FIG. 19 is a schematic process diagram showing an example step of producing a soldered circuit module of the present disclosure.

FIG. 20 is a schematic process diagram showing an example step of producing a soldered circuit module of the present disclosure.

FIG. 21 is a schematic process diagram showing an example step of producing a soldered circuit module of the present disclosure.

FIG. 22 is a schematic process diagram showing an example step of producing a soldered circuit module of the present disclosure.

FIG. 23 is an enlarged schematic view showing the structure around a connection terminal in a circuit module of a sixth embodiment.

FIG. 24 is an enlarged schematic view showing the structure around a connection terminal in a soldered circuit module of the sixth embodiment.

FIG. 25 is an enlarged schematic view showing the structure around a connection terminal in another example circuit module of the sixth embodiment.

FIG. 26 is an enlarged schematic view showing the structure around a connection terminal in another example circuit module of the sixth embodiment.

FIG. 27 is an enlarged schematic view showing the structure around a connection terminal in a circuit module of a seventh embodiment.

FIG. 28 is a plan view of a first modification of the circuit module of the present disclosure, as seen from the surface provided with a resin layer and connection terminals.

FIG. 29 is a plan view of a second modification of the circuit module of the present disclosure, as seen from the surface provided with a resin layer and connection terminals.

### DESCRIPTION OF EMBODIMENTS

Hereinafter, the circuit module and the soldered circuit module of the present disclosure will be described.

The present disclosure is not limited to the following embodiments and may be suitably modified without departing from the gist of the present disclosure. Combinations of two or more features described in the following embodiments are also within the scope of the present disclosure.

The inventors of the present disclosure have recognized that in conventional modules, the intermetallic compound (IMC) layer often aligns with the resin surface, creating a stress concentration point. For example, in the radio-frequency module disclosed in Patent Literature 1, the bondability between the external connection terminals and solder is not considered. The radio-frequency module disclosed in Patent Literature 1 sometimes exhibits low solder wettability when solder is applied to the external connection terminals, which may lead to insufficient bonding strength between the external connection terminals and the solder.

The present disclosure is directed to solving these and other problems to provide a circuit module that, when a connection terminal is bonded to solder, can exhibit high bonding strength between the solder and the connection terminal and high impact resistance at the bonded portion between the connection terminal and the solder.

Furthermore, the present disclosure aims to provide a soldered circuit module that exhibits high bonding strength between solder and a connection terminal, and high impact resistance at the bonded portion between the connection terminal and the solder.

As set forth in the following disclosure, a circuit module that, when a connection terminal is bonded to solder, exhibits high bonding strength between the solder and the connection terminal and high impact resistance at the bonded portion between the connection terminal and the solder may be realized.

Furthermore, a soldered circuit module that exhibits high bonding strength between solder and a connection terminal, and high impact resistance at the bonded portion between the connection terminal and the solder may be realized.

First, the circuit module of the present disclosure is described.

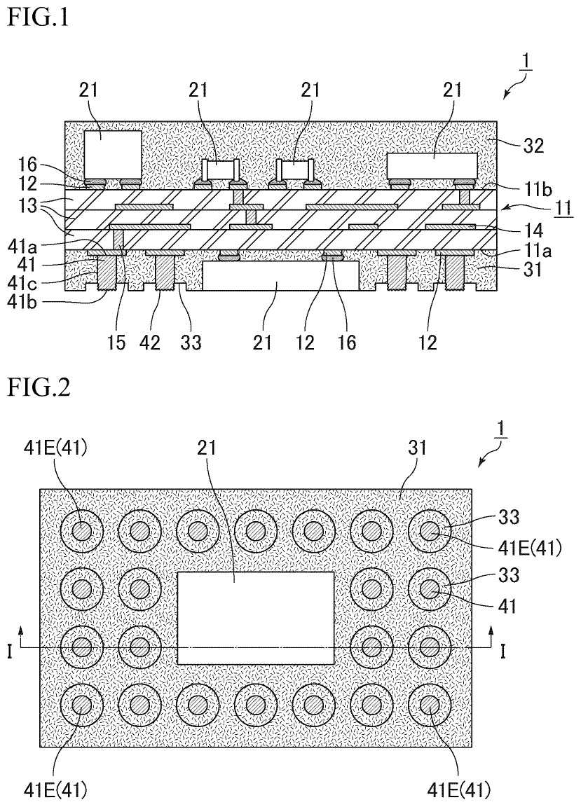

FIG. 1 is a schematic cross-sectional view of an example circuit module of a first embodiment.

FIG. 2 is a plan view of the circuit module of the first embodiment, as seen from the surface provided with a resin layer and connection terminals.

FIG. 1 is a cross-sectional view taken along line I-I in the plan view shown in FIG. 2.

Hereinafter, an example circuit module of the present disclosure will be described with reference to FIG. 1.

A circuit module 1 includes a substrate 11, electronic components 21, a resin layer 31, a resin layer 32, and connection terminals 41.

The substrate 11 includes a first main surface 11a and a second main surface 11b opposite to each other. The first main surface 11a and the second main surface 11b of the substrate 11 each have electrodes 12 disposed thereon. The substrate 11 includes insulating layers 13, and conductors including a patterned conductor 14 and via conductors 15, which are required for the configuration of an electronic circuit.

The substrate 11 is a ceramic substrate in which the insulating layers 13 are formed of, for example, a low-temperature sintering ceramic material. The low-temperature sintering ceramic material is a type of ceramic material that can be co-fired with a metal material such as silver or copper at a firing temperature of 1000° C. or lower. Examples include SiO₂—CaO—Al₂O₃—B₂O₃-based glass ceramics and SiO₂—MgO-Al₂O₃—B₂O₃-based glass ceramics. The type of the insulating layers 13 is not limited thereto. For example, the insulating layers 13 may be formed of a glass epoxy resin, a ceramic material other than low-temperature sintering ceramic materials, glass, or the like. The patterned conductor 14 and the via conductors 15 are formed of a metal material selected from, for example, Cu, Cu alloys, and the like. The material of the patterned conductor 14 and the via conductors 15 is not limited thereto. The substrate 11 may be a multilayered substrate or a single-layer substrate.

The electrodes 12 are formed by plating a surface of a metal material selected from, for example, Cu, Cu alloys, and the like with a metal material selected from Ni, Ni alloys, and the like. However, the material of the electrodes 12 is not limited thereto.

The electronic components 21 are each connected to a corresponding electrode(s) 12 provided on the first main surface 11a of the substrate 11 or on the second main surface 11b of the substrate 11 via a corresponding connection member 16.

The electronic components 21 may be, for example, chip components such as multilayer capacitors, multilayer inductors, or various filters, or semiconductor components such as various ICs or memories. The connection member 16 may be, for example, a Pb-free Sn—Ag—Cu-based solder. However, the material of the connection member 16 is not limited thereto.

In FIG. 1, the electronic components 21 are provided on both the first main surface 11a of the substrate 11 and the second main surface 11b of the substrate 11. The electronic components 21 may be provided on at least one of the first main surface 11a of the substrate 11 or the second main surface 11b of the substrate 11. Also, no electronic components 21 may be provided on the substrate 11.

The resin layer 31 is provided on the first main surface 11a of the substrate 11. The resin layer 32 is provided on the second main surface 11b of the substrate 11. The resin layer 31 and the resin layer 32 may each be formed of a resin composition in which a glass material or silica, for example, is dispersed as a filler in a resin material. The filler may be a high thermal conductivity material. For example, oxides or nitrides such as aluminum oxide, aluminum nitride, or boron nitride may be used, or a configuration in which a metal material such as copper is coated with an insulator may be employed. Alternatively, the resin layer 31 and the resin layer 32 may be layers formed only of a resin material. The resin layer 31 and the resin layer 32 may be formed using the same resin material or different resin materials. In the circuit module 1, a resin layer may not be provided on the second main surface 11b.

Each of the electronic components 21 may be fully covered with the resin layer 31 or the resin layer 32, or the surface of the electronic component 21 may be exposed from the outer surface of the resin layer 31 or the resin layer 32. Herein, the outer surface of the resin layer refers to one of the two main surfaces of the resin layer, opposite to each other in the thickness direction, that is not in contact with the substrate 11.

Each of the connection terminals 41 penetrates, e.g., extends through, the resin layer 31 provided on the first main surface 11a of the substrate 11 in the thickness direction of the resin layer 31. The connection terminal 41 has a first bottom or end surface 41a located adjacent to the substrate 11, a second bottom or end surface 41b opposite to the first bottom surface 41a, and a side surface 41c.

In the circuit module 1, the first bottom surface 41a is in contact with a corresponding electrode 12 provided on the first main surface 11a of the substrate 11. The connection terminal 41 may be in direct contact with the substrate 11 without any electrode 12. A case where the connection terminal 41 is in contact with a corresponding electrode 12 provided on the first main surface 11a of the substrate 11 is also encompassed by the cases where the connection terminal 41 is provided on the first main surface 11a of the substrate and by the cases where the connection terminal 41 penetrates the resin layer 31 provided on first main surface 11a of the substrate 11 in the thickness direction of the resin layer 31.

The second bottom surface 41b is exposed from the resin layer 31.

The shape of the connection terminals 41 is not limited. For example, the connection terminals 41 may be columnar conductors and may be cylindrical, substantially cylindrical, or prismatic in shape. The connection terminals 41 may have a tapered shape such that their width increases toward the first main surface 11a of the substrate 11 in the cross section shown in FIG. 1.

The material of the connection terminal 41 is not limited and may include, e.g., Cu, Ag, Au, Al, Ni, Cr, Ti, and alloys including at least one of these metals.

As shown in FIG. 2, recesses 33 that are recessed toward the first main surface 11a of the substrate 11 are each formed in a region of a surface of the resin layer 31 surrounding the second bottom surface 41b of a corresponding connection terminal 41. The method for forming the recesses 33 is not limited. The recesses 33 may be formed by, for example, removing portions of the resin 31 by laser irradiation.

As shown in FIG. 2, in the circuit module 1, the recesses 33 are provided to surround all of the connection terminals 41. However, a recess 33 may instead be provided to surround only one or more of the connection terminals 41. For example, the recesses 33 may be provided to surround only connection terminals 41E located at the end portions of the circuit module 1.

Although the recesses 33 are provided to surround the respective connection terminals 41 in FIG. 2, the recesses 33 surrounding the connection terminals 41 may be connected to each other. In other words, a single recess 33 may be provided to surround a plurality of connection terminals 41. A modified example in which a single recess 33 is provided to surround a plurality of connection terminals 41 will be described later.

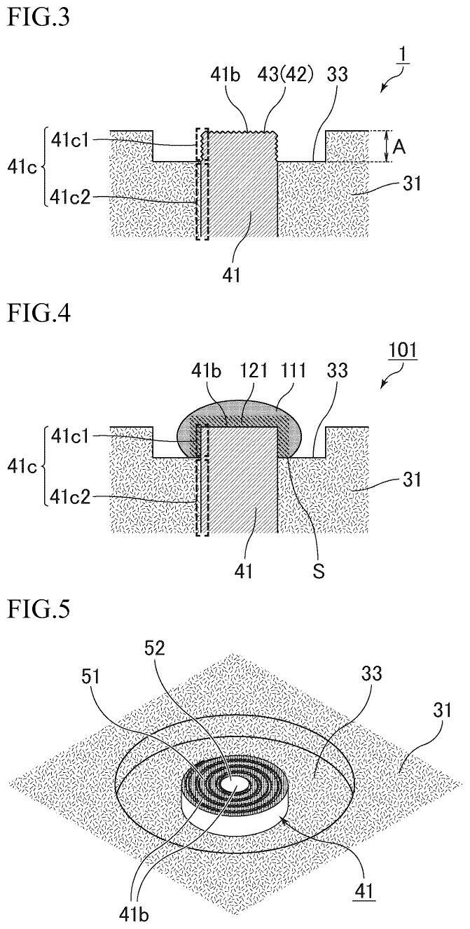

FIG. 3 is an enlarged schematic view showing the structure around a connection terminal in the circuit module of the first embodiment.

FIG. 3, FIG. 4, and FIG. 7 to FIG. 10 each show a state in which the circuit module in FIG. 1 is upside down.

Hereinafter, with reference to FIG. 3, the structure around each connection terminal 41 will be described. FIG. 3 shows a configuration in which the later-described solder wettability improving layer 42 is a surface-roughened layer 43.

As shown in FIG. 3, in the recess 33, a portion of the side surface 41c of the connection terminal 41 is exposed from the resin layer 31. In other words, the side surface 41c of the connection terminal 41 includes a portion 41c1 exposed from the recess 33 and a portion 41c2 not exposed from the recess 33.

A solder wettability improving layer 42 is provided on the second bottom surface 41b of the connection terminal 41 and the portion 41c1 of the side surface 41c of the connection terminal 41 exposed from the recess 33. FIG. 3 shows an example structure in which the solder wettability improving layer 42 is a surface-roughened layer 43.

The solder wettability improving layer is a layer that has been treated to promote solder wetting and spreading on the surface of each connection terminal.

FIG. 4 is a schematic view showing a state where a solder bump is bonded to the connection terminal shown in FIG. 3.

FIG. 4 is a schematic enlarged view showing the structure around the connection terminal 41 in a soldered circuit module 101, in which a solder bump 111 is bonded to the connection terminal 41 of the circuit module 1. When the connection terminal 41 is bonded to the solder bump 111, an intermetallic compound layer 121 is formed in the bonded portion between the connection terminal 41 and the solder bump 111. The intermetallic compound layer 121 thus includes the surface of the connection terminal 41, which was previously defined by the surface-roughened layer 43, so that the surface-roughened layer 43 is no longer visible after the solder bump 111 is bonded.

When various impacts such as temperature changes or drops are applied to the connection terminal 41, stress tends to concentrate on a portion of the connection terminal 41 that lies on the same plane as the surface of the surrounding resin layer 31. If the second bottom surface 41b is located on the same plane as the surrounding resin layer 31 and solder is bonded to the second bottom surface 41b, the intermetallic compound layer 121 formed at the bonded portion between the connection terminal 41 and the solder bump 111 will also be located on the same plane as the surrounding resin layer 31. Since the intermetallic compound layer 121 has low mechanical strength and tends to serve as a fracture origin when an impact is applied, if the intermetallic compound layer 121 is on the same plane as the surrounding resin layer 31, stress is likely to concentrate on the brittle intermetallic compound, resulting in reduced impact resistance.

On the other hand, in the circuit module 1 of the present disclosure, the second bottom surface 41b of the connection terminal 41 protrudes from the surrounding recess 33. Thus, the intermetallic compound layer 121 formed at the bonded portion between the second bottom surface 41b and the solder bump 111 also protrudes from the surrounding recess 33. As a result, the position where the stress is concentrated (the portion indicated by “S” in FIG. 4) and the position of the intermetallic compound layer 121 formed at the bonded portion between the second bottom surface 41b and the solder bump 111 are spaced apart from each other, which can increase the impact resistance when the solder bump 111 is bonded to the connection terminal 41.

Next, the effect of providing the solder wettability improving layer 42 will be described.

When the solder bump 111 is bonded to a connection terminal 41 in which a portion of the side surface 41c is exposed from the recess 33, the solder bump 111 does not easily wet or spread onto the side surface 41c. For example, when the connection terminal 41 is mainly composed of Cu and the solder wettability improving layer 42 is not provided on the surface of the connection terminal 41, the wettability between the connection terminal 41 and the solder bump 111 is poor, so that the solder bump 111 is bonded only to the second bottom surface 41b of the connection terminal 41 without wetting or spreading onto the side surface 41c. In contrast, in the circuit module of the present disclosure, the solder wettability improving layer 42 is provided on the second bottom surface 41b of the connection terminal 41 and on the portion 41c1 of the side surface 41c of the connection terminal 41 exposed from the recess 33. Thus, when the solder bump 111 is bonded to the connection terminal 41, the solder bump 111 wets and spreads onto the side surface 41c of the connection terminal 41.

In FIG. 3, the solder wettability improving layer 42 is provided on the second bottom surface 41b of the connection terminal 41 and on the entire portion 41c1 of the side surface 41c of the connection terminal 41 exposed from the recess 33. However, as long as the effect of the present disclosure can be achieved, the solder wettability improving layer 42 may be provided on the second bottom surface 41b of the connection terminal 41 and on part of the portion 41c1 of the side surface 41c of the connection terminal 41.

In the circuit module 1 of the first embodiment, the solder wettability improving layer 42 is the surface-roughened layer 43. In FIG. 3, the surface-roughened layer 43 is provided on the second bottom surface 41b of the connection terminal 41 and on the entire portion 41c1 of the side surface 41c of the connection terminal 41 exposed from the recess 33. However, as long as the effect of the present disclosure can be achieved, the surface-roughened layer 43 may be provided on the second bottom surface 41b of the connection terminal 41 and on part of the portion 41c1 of the side surface 41c of the connection terminal 41 exposed from the recess 33.

The surface-roughened layer refers to a layer exhibiting a high surface roughness Sa (a surface exhibiting a high surface roughness Sa) compared to a surface that has not undergone a surface roughening treatment. The surface-roughened layer has high wettability with solder. The method for forming a surface-roughened layer is not limited. Examples include chemical methods such as etching using a sulfuric acid-hydrogen peroxide-based etchant, and physical methods such as sandblasting and roughening with a file.

The surface roughness Sa refers to an arithmetic mean surface roughness Sa. The arithmetic mean surface roughness Sa can be measured, for example, using a 3D laser scanning microscope (VR-3000 available from Keyence Corporation).

The surface roughness Sa of the surface-roughened layer 43 may be 0.3 μm or greater and 1.5 μm or less.

When the recess 33 of the resin layer 31 is formed by laser irradiation, a laser-irradiation trace may be present on the second bottom surface 41b of the connection terminal 41. To prevent resin components from remaining on the side surface 41c of the connection terminal 41 due to positional misalignment during laser irradiation caused by distortion of the substrate 11 or the like, part or all of the second bottom surface 41b of the connection terminal 41 may be irradiated with a laser. In such a case, a laser-irradiation trace may be formed on part or all of the second bottom surface 41b of the connection terminal 41. The laser-irradiation trace is not included in the surface-roughened layer 43 that serves as the solder wettability improving layer 42.

When a laser-irradiation trace is present on the second bottom surface 41b of the connection terminal 41, the second bottom surface 41b having the laser-irradiation trace may be subjected to a surface roughening treatment to form the surface-roughened layer 43. Furthermore, as described later, when the solder wettability improving layer is a metal plating such as a Ni-based plating, both the portion not irradiated with a laser and the laser-irradiation trace may be covered with the metal plating such as a Ni-based plating.

FIG. 5 is a schematic view of an example laser-irradiation trace on a connection terminal.

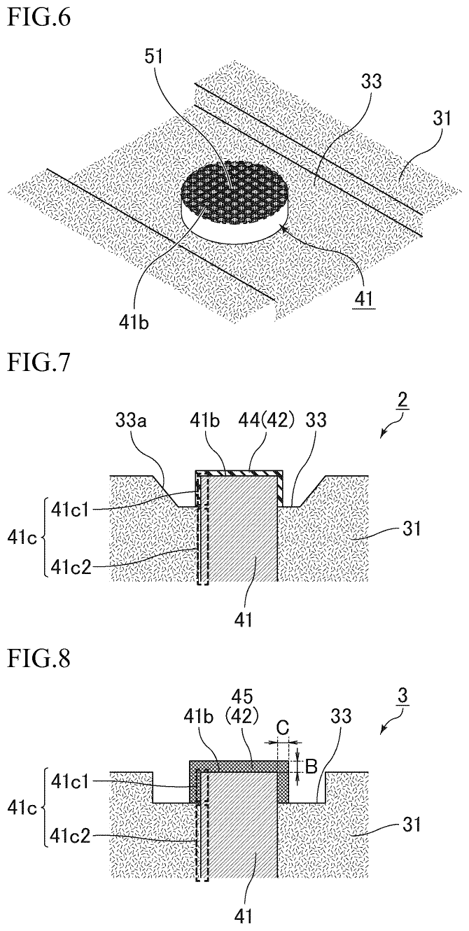

FIG. 6 is a schematic view showing another example laser-irradiation trace on a connection terminal.

FIG. 5 and FIG. 6 are each a schematic view of a connection terminal 41 as seen from its second bottom surface 41b.

In FIG. 5, a recess 33 having a circular cross-sectional shape is provided to surround a connection terminal 41.

In FIG. 5, a laser-irradiation trace 51 is present only on a portion of the second bottom surface 41b of the connection terminal 41. When the laser-irradiation trace 51 is present only on a portion of the second bottom surface 41b of the connection terminal 41, the position of the laser-irradiation trace 51 is not limited. In FIG. 5, the laser-irradiation trace 51 is present so as to surround a laser-unirradiated portion 52.

The laser-irradiation trace 51 refers to a region where irregularities are formed on the surface by laser irradiation. In FIG. 5, the laser-irradiation trace 51 includes spiral-shaped indentations.

In FIG. 6, a groove-shaped recess 33 is provided to surround a connection terminal 41. The groove-shaped recess 33 may surround a plurality of connection terminals 41.

In FIG. 6, the laser-irradiation trace 51 is present over the entire second bottom surface 41b of the connection terminal 41. The laser-irradiation trace 51 shown in FIG. 6 includes grid-shaped indentations.

Hereinafter, with reference to FIG. 3, example dimensions of components such as the connection terminals 41, the resin layer 31, and the recesses 33 will be described.

When the connection terminals 41 are cylindrical or substantially cylindrical, the radius may be 50 μm or greater and 150 μm or less.

The height of the connection terminals 41 may be 50 μm or greater and 200 μm or less.

The thickness of the resin layer 31 may be 50 μm or greater and 200 μm or less. The thickness of the resin layer 31 refers to the thickness measured at the position where the thickness is greatest.

The depth of the recesses 33 (the length indicated by the double-headed arrow “A” in FIG. 3) may be, but is not limited to, for example, 5 μm or greater and 50 μm or less. The depth of the recesses 33 refers to the depth measured at the position where the depth is greatest.

Hereinafter, specific example configurations of the recesses 33 and the connection terminals 41 will be described.

The recesses 33 may have a greater depth in the vicinity of the connection terminals 41. For example, to suppress a reduction in substrate strength, improve productivity in laser processing, and enhance the reliability of the circuit module, each recess 33 may include a vicinity portion adjacent to a corresponding connection terminal 41 and an outer portion remote from the connection terminal 41, and the depth of the vicinity portion may be greater than the depth of the outer portion.

The recesses 33 may contain more filler components than portions of the surface of the resin layer 31 that are not irradiated with a laser (i.e., portions other than the recesses 33 of the surface of the resin layer 31).

Electrode components may not adhere to the vicinity portions of the connection terminals 41 within the recesses 33. The electrode components include, for example, Cu, Ni, and Au. An electrode component such as Cu, Ni, or Au that scatters from electrodes and adheres to the resin surface during laser processing may cause plating deposition on non-electrode portions during a plating process, or may cause solder to adhere to such an electrode component during solder bump formation, resulting in unintended solder coating on non-electrode portions. Therefore, these electrode components may not adhere to the vicinity portions of the connection terminals 41.

A resin component may be present on the portion 41c1 of the side surface 41c of each connection terminal 41 exposed from a corresponding recess 33. The resin component may be derived from the resin layer 31 or may be a filler component. To suppress inhibition of plating deposition or solder bump formation, a resin component may not be present on the portion 41c1 of the side surface 41c of the connection terminal 41 exposed from the recess 33. Whether or not a resin component is present on the portion 41c1 of the side surface 41c of the connection terminal 41 exposed from the recess 33 can be determined by scanning electron microscopy-energy dispersive X-ray spectroscopy (SEM-EDX).

FIG. 7 is an enlarged schematic view showing the structure around a connection terminal in a circuit module of a second embodiment.

In a circuit module 2 of the second embodiment, the solder wettability improving layer 42 is an OSP-treated layer 44. In FIG. 7, the OSP-treated layer 44 is provided on the second bottom surface 41b of the connection terminal 41 and on the entire portion 41c1 of the side surface 41c of the connection terminal 41 exposed from the recess 33. However, as long as the effect of the present disclosure can be achieved, the OSP-treated layer 44 may be provided on the second bottom surface 41b of the connection terminal 41 and on part of the portion 41c1 of the side surface 41c of the connection terminal 41 exposed from the recess 33.

The OSP-treated layer is a layer subjected to an organic solderability preservative treatment (water-soluble pre-flux treatment). The term “OSP treatment” refers to a treatment of forming an organic film on the surface of the object to prevent oxidation of the surface of the object. The OSP-treated layer includes an organic film formed on the surface of the connection terminal 41. The OSP-treated layer can suppress a decrease in wettability of the surface of the connection terminal 41 with solder due to oxidation of the surface of the connection terminal 41. Accordingly, the OSP-treated layer improves the wettability between the connection terminal 41 and solder. The method for forming an OSP-treated layer is not limited. For example, an OSP treatment may be performed using a commercially available pre-flux solution.

The OSP-treated layer 44 may be a layer subjected to both a surface roughening treatment and an OSP treatment. For example, the OSP-treated layer 44 may be formed by subjecting the surface to a surface roughening treatment and subsequently an OSP treatment.

Additionally, FIG. 7 shows an example in which a side surface or recessed surface 33a of the recess 33 opposite to the connection terminal 41 has a tapered shape such that the depth of the recess 33 decreases as the distance from the connection terminal 41 increases. Such a shape may be formed by forming the recess 33 by laser processing. In circuit modules of other embodiments, the side surface 33a of the recess 33 opposite to the connection terminal 41 may have a tapered shape such that the depth of the recess 33 decreases as the distance from the connection terminal 41 increases.

FIG. 8 is an enlarged schematic view showing the structure around a connection terminal in a circuit module of a third embodiment.

In the circuit module of the third embodiment, the solder wettability improving layer is a plating layer. The plating layer may be a NiAu plating layer or a NiPdAu plating layer.

In a circuit module 3 of the third embodiment shown in FIG. 8, the solder wettability improving layer 42 is a Ni-based plating layer 45. In FIG. 8, the Ni-based plating layer 45 is provided on the second bottom surface 41b of the connection terminal 41 and on the entire portion 41c1 of the side surface 41c of the connection terminal 41 exposed from the recess 33. However, as long as the effect of the present disclosure can be achieved, the Ni-based plating layer 45 may be provided on the second bottom surface 41b of the connection terminal 41 and on part of the portion 41c1 of the side surface 41c of the connection terminal 41 exposed from the recess 33.

In the circuit module 3, the Ni-based plating layer 45 may be any plating layer containing Ni, and is, for example, a NiAu plating layer or a NiPdAu plating layer. In other words, the solder wettability improving layer 42 may be a NiAu plating layer or a NiPdAu plating layer.

The NiAu plating layer is a plating layer containing nickel (Ni) and gold (Au). The NiAu plating layer may include a Ni plating layer and an Au plating layer. For example, a Ni plating layer may be provided on the surface of the connection terminal 41, and an Au plating layer may be provided on the surface of the Ni plating layer. Such a NiAu plating layer can be formed by plating the connection terminal 41 with Ni and then with Au.

The method for forming a NiAu plating layer is not limited, and may be an electroplating method or an electroless plating method.

A NiPdAu plating layer is a plating layer containing nickel (Ni), palladium (Pd), and gold (Au). The NiPdAu plating layer may include a Ni plating layer, a Pd plating layer, and a Au plating layer. For example, a Ni plating layer may be provided on the surface of the connection terminal 41, a Pd plating layer may be provided on the surface of the Ni plating layer, and a Au plating layer may be provided on the surface of the Pd plating layer. Such a NiPdAu plating layer can be formed by plating the connection terminal 41 with Ni, then with Pd, and subsequently with Au.

The method for forming a NiPdAu plating layer is not limited, and may be an electroplating method or an electroless plating method.

When the connection terminal 41 provided with the Ni-based plating layer 45 is bonded to a solder bump, a Ni-plating-derived layer derived from a Ni-based plating layer 45 may be present between the connection terminal 41 and the intermetallic compound layer.

The ratio of the thickness “C” (the length indicated by the double-headed arrow “C” in FIG. 8) of the Ni-based plating layer 45 provided on the side surface 41c of the connection terminal 41 to the thickness “B” (the length indicated by the double-headed arrow “B” in FIG. 8) of the Ni-based plating layer 45 provided on the second bottom surface 41b of the connection terminal 41 may be, for example, C/B=0.8 or greater and 1.2 or less. In this case, the influence of the thickness of the Ni-based plating layer 45 on the diameter and height of the connection terminal 41 can be suppressed.

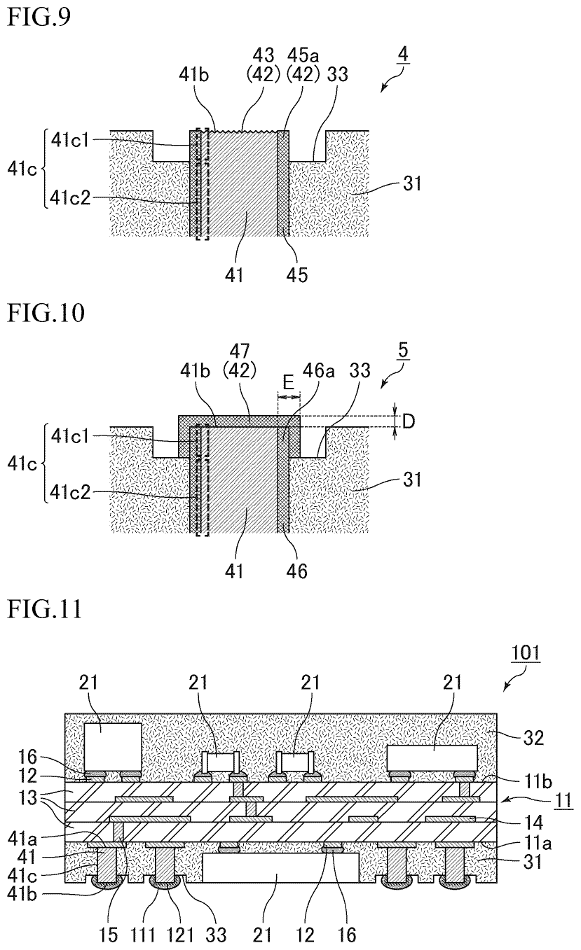

FIG. 9 is an enlarged schematic view showing the structure around a connection terminal in a circuit module of a fourth embodiment.

In a circuit module 4 of the fourth embodiment, the surface-roughened layer 43 is provided as the solder wettability improving layer 42 on the second bottom surface 41b of the connection terminal 41. In the circuit module 4 of the fourth embodiment, the Ni-based plating layer 45 is provided on the entire side surface 41c of the connection terminal 41, and a portion 45a of the Ni-based plating layer 45 exposed from the recess 33 serves as the solder wettability improving layer 42.

The Ni-based plating layer 45 is provided on the entire side surface 41c of the connection terminal 41. Specifically, the Ni-based plating layer 45 is provided also on a portion of the side surface 41c of the connection terminal 41 surrounded by the resin layer 31. In other words, a portion of the Ni-based plating layer 45 is covered with the resin layer 31.

In the circuit module 4, the Ni-based plating layer 45 is, for example, a NiAu plating layer. In other words, a NiAu plating layer may be provided on the entire side surface 41c of the connection terminal 41, and a portion of the NiAu plating layer exposed from the recess 33 may serve as the solder wettability improving layer 42. In the circuit module 4, the Ni-based plating layer 45 may be, for example, a NiPdAu plating layer.

The surface-roughened layer 43 in the circuit module 4 of the fourth embodiment may be replaced with the OSP-treated layer 44 shown in FIG. 7. In other words, on the second bottom surface 41b of the connection terminal 41, the surface-roughened layer 43 or the OSP-treated layer 44 may be provided as the solder wettability improving layer 42, or the OSP-treated layer 44 may be provided.

In FIG. 9, the surface-roughened layer 43 is provided only on the second bottom surface 41b of the connection terminal 41. However, the surface of the portion 45a of the Ni-based plating layer 45 exposed from the recess 33 may also be subjected to a surface roughening treatment or an OSP treatment.

FIG. 10 is an enlarged schematic view showing the structure around a connection terminal in a circuit module in a fifth embodiment.

In a circuit module 5 of the fifth embodiment, a first Ni-based plating layer 46 is provided on the entire side surface 41c of the connection terminal 41. A portion of the first Ni-based plating layer 46 is exposed from the recess 33. Additionally, a second Ni-based plating layer 47 is provided as the solder wettability improving layer 42 on the second bottom surface 41b of the connection terminal 41 and on a portion 46a of the first Ni-based plating layer 46 exposed from the recess 33.

The first Ni-based plating layer 46 is provided on the entire side surface 41c of the connection terminal 41. A portion of the first Ni-based plating layer 46 is covered with the resin layer 31. The portion 46a of the first Ni-based plating layer 46 exposed from the recess 33 is covered with the second Ni-based plating layer 47.

The second Ni-based plating layer 47 is provided on the second bottom surface 41b of the connection terminal 41 and on the portion 41c1 of the side surface 41c of the connection terminal 41 exposed from the recess 33.

The first Ni-based plating layer 46 is, for example, a NiAu plating layer. The second Ni-based plating layer 47 is, for example, a NiAu plating layer or a NiPdAu plating layer. In other words, a first NiAu plating layer may be provided on the entire side surface 41c of the connection terminal 41. A second NiAu plating layer or a NiPdAu plating layer may be provided as the solder wettability improving layer 42 on the second bottom surface 41b of the connection terminal 41 and on the portion 41c1 of the side surface 41c of the connection terminal 41 exposed from the recess 33. The first NiAu plating layer on the portion 41c1 of the side surface 41c of the connection terminal 41 exposed from the recess 33 may be covered with the second NiAu plating layer or the NiPdAu plating layer.

The first Ni-based plating layer 46 and the second Ni-based plating layer 47 may be integrated without a visible interface.

The ratio of the total thickness “E” (the length indicated by the double-headed arrow “E” in FIG. 10) of the thickness of the first Ni-based plating layer 46 provided on the side surface 41c of the connection terminal 41 and the thickness of the second Ni-based plating layer 47 to the thickness “D” (the length indicated by the double-headed arrow “D” in FIG. 10) of the second Ni-based plating layer 47 provided on the second bottom surface 41b of the connection terminal 41 may be, for example, E/D=1.2 or greater and 3.3 or less. In this case, the influence of the thickness of the first Ni-based plating layer 46 and the thickness of the second Ni-based plating layer 47 on the diameter and height of the connection terminal 41 can be suppressed.

The Ni-based plating layers 45 in the third embodiment and the fourth embodiment, and the first Ni-based plating layer 46 and the second Ni-based plating layer 47 in the fifth embodiment may each be a different Ni-based plating layer that enhances the solder wettability. Examples of the different Ni-based plating layer include NiAg plating layers.

When the Ni-based plating layer 45, the first Ni-based plating layer 46, or the second Ni-based plating layer 47 is formed by electroless plating, the Ni-based plating layer 45, the first Ni-based plating layer 46, or the second Ni-based plating layer 47 may be a plating in which a component derived from a reducing agent is co-deposited, such as a Ni—P plating or a Ni—B plating.

The Ni-based plating layers 45 in the third embodiment and the fourth embodiment, and the first Ni-based plating layer 46 and the second Ni-based plating layer 47 in the fifth embodiment may each be replaced with a non-Ni-based plating layer that can enhance the solder wettability. In other words, in the present disclosure, the solder wettability improving layer 42 may be a non-Ni-based plating layer. Examples of the non-Ni-based plating layer that is to serve as the solder wettability improving layer 42 include a PdAu plating layer, an AuPdAu plating layer, an Ag plating layer, and an Au plating layer.

Next, the soldered circuit module of the present disclosure will be described.

The soldered circuit module of the present disclosure is one in which solder is bonded to the connection terminal of the circuit module of the present disclosure.

FIG. 11 is a schematic cross-sectional view of an example soldered circuit module of the first embodiment.

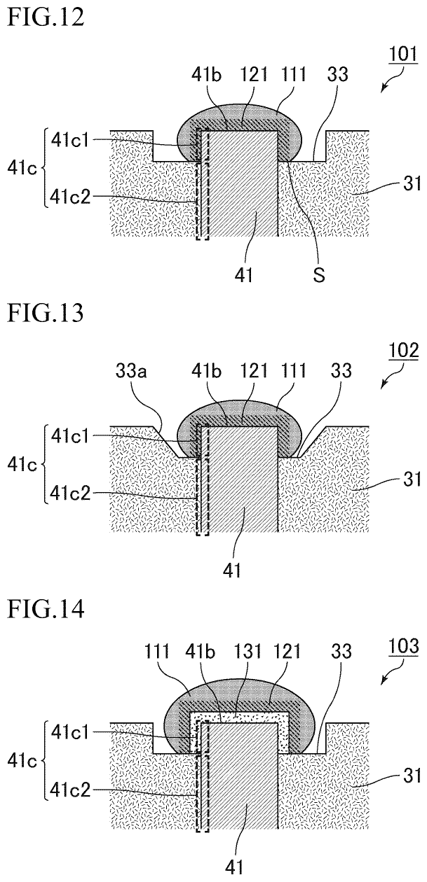

FIG. 12 is an enlarged schematic view showing the structure around a connection terminal in the soldered circuit module of the first embodiment.

FIG. 12 to FIG. 16 each show a state where the soldered circuit module in FIG. 11 is upside down.

A soldered circuit module 101 of the first embodiment can be obtained by bonding the solder bumps 111 to the connection terminals 41 of the circuit module 1 of the first embodiment shown in FIG. 1 to FIG. 3. FIG. 12 is the same drawing as FIG. 4 in which the solder bump 111 is bonded to a corresponding connection terminal 41 of the circuit module 1. In this case, the intermetallic compound layer 121 includes the surface of the connection terminal 41, which was previously defined by the surface-roughened layer 43, so that the surface-roughened layer 43 is no longer visible after the solder bump 111 is bonded.

The soldered circuit module 101 includes the substrate 11, the electronic components 21, the resin layer 31, the resin layer 32, the connection terminals 41, and the solder bumps 111.

The substrate 11 includes the first main surface 11a and the second main surface 11b opposite to each other. The first main surface 11a and the second main surface 11b of the substrate 11 each have electrodes 12 disposed thereon. The substrate 11 includes the insulating layers 13, and conductors including the patterned conductor 14 and the via conductors 15, which are required for the configuration of an electronic circuit.

The electronic components 21 are each connected to a corresponding electrode(s) 12 provided on the first main surface 11a of the substrate 11 or on the second main surface 11b of the substrate 11 via a corresponding connection member 16.

The resin layer 31 is provided on the first main surface 11a of the substrate 11. The resin layer 32 is provided on the second main surface 11b of the substrate 11.

The configurations of the substrate 11, the electronic components 21, and the resin layer 31 in the soldered circuit module 101 are the same as the configurations of the respective components in the circuit module 1. Thus, detailed descriptions thereof are omitted.

Each of the connection terminals 41 penetrates the resin layer 31 provided on the first main surface 11a of the substrate 11 in the thickness direction of the resin layer 31.

The connection terminal 41 has a first bottom surface 41a located adjacent to the substrate 11, a second bottom surface 41b opposite to the first bottom surface 41a, and a side surface 41c.

The second bottom surface 41b is not covered with the resin layer 31. A recess 33 that is recessed toward the first main surface 11a of the substrate 11 is formed in a region of a surface of the resin layer 31 surrounding the second bottom surface 41b of a corresponding connection terminal 41. In the recess 33, a portion of the side surface 41c of the connection terminal 41 is exposed from the resin layer 31. In other words, the side surface 41c of the connection terminal 41 includes a portion 41c1 exposed from the recess 33 and a portion 41c2 not exposed from the recess 33.

As described above, since the recess 33 that is recessed toward the first main surface 11a of the substrate 11 is formed in a region surrounding the second bottom surface 41b of a corresponding connection terminal 41, the second bottom surface 41b protrudes from the surrounding resin layer 31.

The solder bump 111 is provided to cover the second bottom surface 41b of the connection terminal 41 and at least part of the portion 41c1 of the side surface 41c of the connection terminal 41 exposed from the recess 33. The solder bump 111 is bonded to the connection terminal 41 via the intermetallic compound layer 121.

The intermetallic compound layer 121 is present between the connection terminal 41 and the solder bump 111. The intermetallic compound layer 121 covers the second bottom surface 41b of the connection terminal 41 and at least part of the portion 41c1 of the side surface 41c of the connection terminal 41 exposed from the recess 33.

In the soldered circuit module 101, the solder bump 111 covers both the second bottom surface 41b of each connection terminal 41 and a portion of the side surface 41c of the connection terminal 41. Therefore, the bonding strength between the connection terminal 41 and the solder bump 111 can be increased.

Additionally, in the soldered circuit module 101, the intermetallic compound layer 121 in each recess 33 is formed at an upper position in FIG. 12 of the recess 33 (the position corresponding to the second bottom surface 41b of the connection terminal 41). As a result, the position where the stress is concentrated (the portion indicated by “S” in FIG. 12) and the position of the intermetallic compound layer 121 formed on the second bottom surface 41b are spaced apart from each other, which can increase the impact resistance of the bonded portion between the connection terminal 41 and the solder bump 111.

In FIG. 12, the solder bump 111 and the intermetallic compound layer 121 cover the second bottom surface 41b of the connection terminal 41 and the entire portion 41c1 of the side surface 41c of the connection terminal 41 exposed from the recess 33. In other words, the solder bump 111 and the intermetallic compound layer 121 extend to the surface of the resin layer 31 recessed in the recess 33, such that the intermetallic compound layer 121 is vertically offset from the non-recessed outer surface 31a of the resin layer 31. This offset ensures that mechanical stress applied at the resin surface 31a does not coincide with the brittle interface of the intermetallic compound layer 121. In this case, the bonding strength between the connection terminal 41 and the solder bump 111 can be further enhanced.

The solder bump 111 and the intermetallic compound layer 121 may cover only part of the portion 41c1 of the side surface 41c of the connection terminal 41 exposed from the recess 33. In other words, the solder bump 111 and the intermetallic compound layer 121 may not extend to the surface of the resin layer 31 recessed in the recess 33.

The soldered circuit module 101 may be mounted on another substrate (e.g., printed circuit board) via the solder bumps 111. Alternatively, the solder bumps 111 may be defined by solder that has been pre-coated before mounting on another substrate. In this case, when the soldered circuit module 101 is mounted on another substrate, additional solder may be supplied to the solder bumps 111 as needed to perform soldering.

FIG. 13 is an enlarged schematic view showing the structure around a connection terminal in a soldered circuit module of the second embodiment.

A soldered circuit module 102 of the second embodiment can be obtained by bonding solder bumps 111 to the connection terminals 41 of the circuit module 2 of the second embodiment shown in FIG. 7. In this case, the OSP-treated layer 44 in the circuit module 2 is no longer visible in the soldered circuit module 102.

For the above reasons, the soldered circuit module 102 of the second embodiment shown in FIG. 13 has the same configuration as the soldered circuit module 101 of the first embodiment shown in FIG. 11 and FIG. 12, except that the side surface 33a of the recess 33 opposite to the connection terminal 41 has a tapered shape such that the depth of the recess 33 decreases as the distance from the connection terminal 41 increases.

In soldered circuit modules of other embodiments, the side surface 33a of the recess 33 opposite to the connection terminal 41 may have a tapered shape such that the depth of the recess 33 decreases as the distance from the connection terminal 41 increases.

FIG. 14 is an enlarged schematic view showing the structure around a connection terminal in a soldered circuit module of the third embodiment.

A soldered circuit module 103 of the third embodiment can be obtained by bonding the solder bumps 111 to the connection terminals 41 of the circuit module 3 of the third embodiment shown in FIG. 8.

In the soldered circuit module 103, a Ni-plating-derived layer 131 is present between the connection terminal 41 and the intermetallic compound layer 121.

The Ni-plating-derived layer 131 contains Ni. The Ni-plating-derived layer 131 may be a layer derived from the Ni-based plating layer 45 in FIG. 8.

In FIG. 14, the Ni-plating-derived layer 131 is present over the entire region between the connection terminal 41 and the intermetallic compound layer 121. However, the Ni-plating-derived layer 131 may be present only in a portion of the region between the connection terminal 41 and the intermetallic compound layer 121.

The method for determining the presence of the Ni-plating-derived layer 131 may be, for example, observing the bonded portion between the connection terminal 41 and the solder bump 111 in a cross section of the soldered circuit module 103 by scanning electron microscopy-energy dispersive X-ray spectroscopy (SEM-EDX).

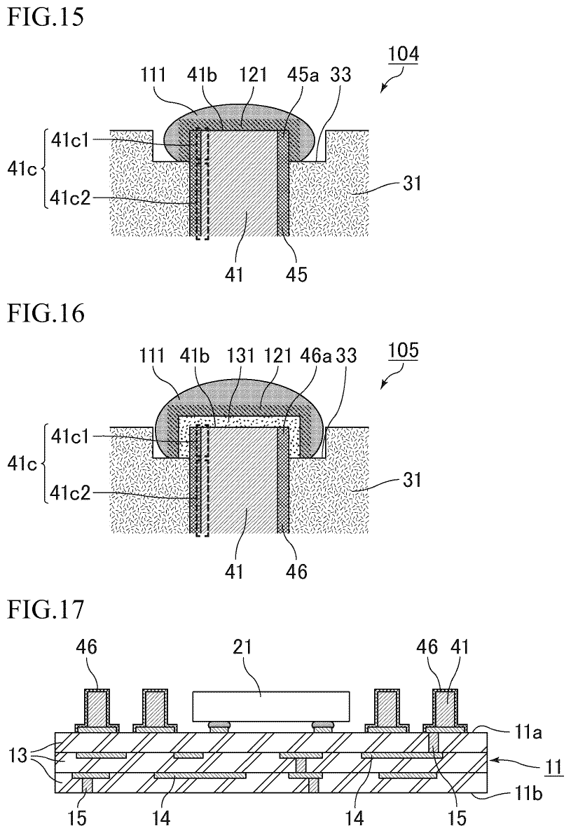

FIG. 15 is an enlarged schematic view showing the structure around a connection terminal in a soldered circuit module of the fourth embodiment.

A soldered circuit module 104 of the fourth embodiment can be obtained by bonding the solder bumps 111 to the connection terminals 41 of the circuit module 4 of the fourth embodiment shown in FIG. 9.

In the soldered circuit module 104 of the fourth embodiment, the Ni-based plating layer 45 is provided on the entire side surface 41c of the connection terminal 41. In FIG. 15, the solder bump 111 and the intermetallic compound layer 121 cover the entire portion 45a of the Ni-based plating layer 45 exposed from the recess 33. The solder bump 111 and the intermetallic compound layer 121 may cover only part of the portion 45a of the Ni-based plating layer 45 exposed from the recess 33.

The Ni-based plating layer 45 in the soldered circuit module 104 is, for example, a NiAu plating layer. The Ni-based plating layer 45 in the soldered circuit module 104 may be a NiPdAu plating layer or a NiAg plating layer, for example.

The portion 45a of the Ni-based plating layer 45 exposed from the recess 33 may be a Ni-plating-derived layer. In this case, the Ni-plating-derived layer covers the side surface 41c of the connection terminal 41, and the Ni-plating-derived layer is not present on the second bottom surface 41b of the connection terminal 41.

FIG. 16 is an enlarged schematic view showing the structure around a connection terminal in a soldered circuit module of the fifth embodiment.

A soldered circuit module 105 of the fifth embodiment can be obtained by bonding the solder bumps 111 to the connection terminals 41 of the circuit module 5 of the fifth embodiment shown in FIG. 10.

In the soldered circuit module 105 of the fifth embodiment, the first Ni-based plating layer 46 is provided on the entire side surface 41c of the connection terminal 41. Also, the Ni-plating-derived layer 131 is present between the connection terminal 41 and the intermetallic compound layer 121. The Ni-plating-derived layer 131 is mainly derived from the second Ni-based plating layer 47 (see FIG. 10). Additionally, the Ni-plating-derived layer 131 is present between the portion 46a of the first Ni-based plating layer 46 exposed from the recess 33 and the intermetallic compound layer 121. The interface between the Ni-plating-derived layer 131 and the first Ni-based plating layer 46 may not be visible.

Next, a method for producing the circuit module and the soldered circuit module of the present disclosure will be described. The following describes an example method for producing the soldered circuit module 105 shown in FIG. 16 with reference to FIG. 17 to FIG. 22, including producing the circuit module 5 shown in FIG. 10 and bonding the solder bumps 111 to the circuit module 5.

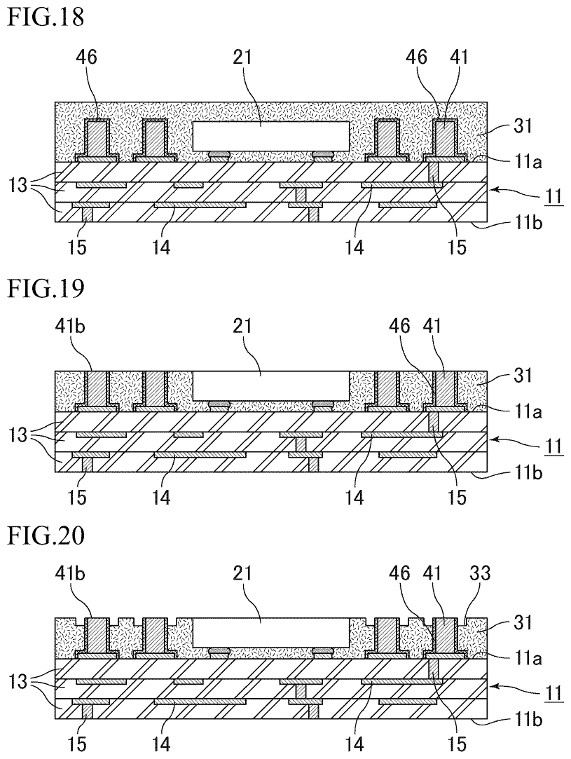

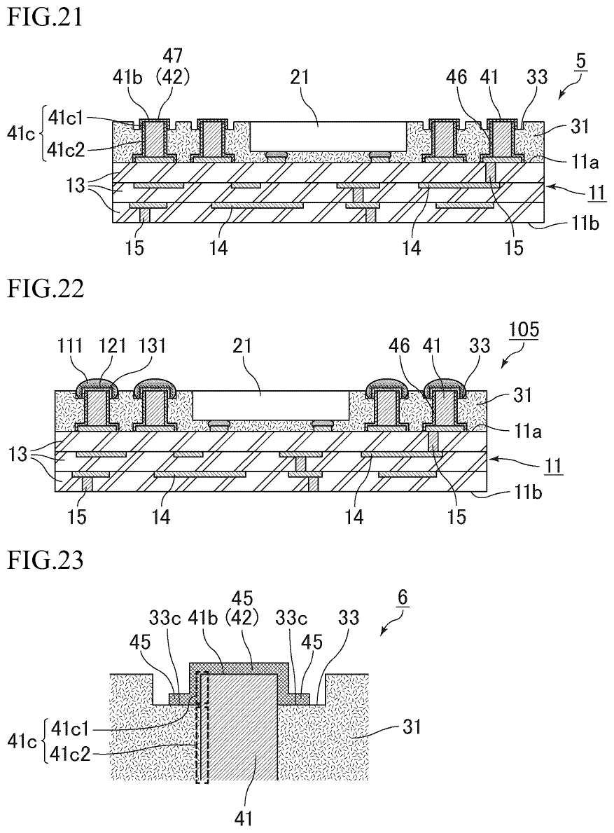

FIG. 17, FIG. 18, FIG. 19, FIG. 20, FIG. 21, and FIG. 22 are schematic process diagrams each showing an example step of producing a soldered circuit module of the present disclosure.

Hereinafter, the step of forming the resin layers and the subsequent steps among the steps of producing the soldered circuit module of the present disclosure will be described.

FIG. 17 shows a state where the connection terminals 41 are formed on the first main surface 11a of the substrate 11. The first Ni-based plating layer 46 is formed to cover the connection terminals 41 except for the portion of each connection terminal 41 in contact with the first main surface 11a. The first Ni-based plating layer 46 is, for example, a NiAu plating layer. In FIG. 17 to FIG. 22, the configurations of the components adjacent to the second main surface 11b of the substrate 11, including the electronic components and the resin layer, are omitted.

Next, as shown in FIG. 18, the resin layer 31 is formed on the first main surface 11a of the substrate 11 so as to cover all of the electronic components 21, the connection terminals 41, and the first Ni-based plating layer 46. The step of forming the resin layer 31 on the first main surface 11a of the substrate 11 can be performed by a known technique such as applying a resin material for forming the resin layer 31 to the first main surface 11a of the substrate 11.

Next, as shown in FIG. 19, the electronic components 21, the connection terminals 41, the first Ni-based plating layer 46, and the resin layer 31 are subjected to polishing from the surface of the resin layer 31 opposite to the surface of the resin layer 31 that is in contact with the substrate 11. In this process, polishing is performed to a position where the polished surfaces of the connection terminals 41 are exposed, whereby the second bottom surfaces 41b of the connection terminals 41 are exposed from the resin layer 31. The second bottom surfaces 41b of the connection terminals 41 are no longer covered with the first Ni-based plating layer 46.

Next, as shown in FIG. 20, recesses 33 are formed in regions each surrounding the second bottom surface 41b of a corresponding connection terminal 41 in the surface of the resin layer 31. The recesses 33 can be obtained by irradiating the surface of the resin layer 31 with a laser to remove portions of the resin layer 31. The laser irradiation conditions are not limited as long as portions of the resin layer 31 can be removed. The type of laser is not limited and may be, for example, a UV laser, an IR laser, or a visible light laser.

If resin residue remains on the side surface 41c of a connection terminal 41, it may hinder plating deposition or solder wetting on the side surfaces of the electrodes. Therefore, after laser irradiation, a desmear treatment may be performed on the portion 41c1 of the side surface 41c of each connection terminal 41 that is exposed from a corresponding recess 33. The term “desmear treatment” refers to a process of removing resin residue generated during laser processing. The desmear treatment may also be performed on the second bottom surface 41b of each connection terminal 41, or both on the second bottom surface 41b of each connection terminal 41 and on the portion 41c1 of the side surface 41c of the connection terminal 41 exposed from a corresponding recess 33. The method for desmear treatment may be a treatment using a chemical solution (desmear solution) containing permanganate salts such as sodium permanganate or potassium permanganate, or a plasma treatment using a plasma cleaning apparatus with an O₂+CF₄-based gas.

Next, as shown in FIG. 21, the second Ni-based plating layer 47 is formed to cover the second bottom surface 41b of each connection terminal 41 and the portion 41c1 of the side surface 41c of the connection terminal 41 exposed from a corresponding recess 33. The second Ni-based plating layer 47 serves as the solder wettability improving layer 42. The second Ni-based plating layer 47 is, for example, a NiAu plating layer or a NiPdAu plating layer. Thereby, the circuit module 5 is obtained.

Next, as shown in FIG. 22, the solder bumps 111 are formed by bonding solder to the connection terminals 41. In this process, the intermetallic compound layer 121 is formed between each connection terminal 41 and a corresponding solder bump 111. Additionally, the Ni-plating-derived layer 131 is formed between each connection terminal 41 and a corresponding intermetallic compound layer 121. Thereby, the soldered circuit module 105 is obtained.

When the circuit module 1 shown in FIG. 3 is produced and then the soldered circuit module 101 shown in FIG. 12 is produced, a substrate provided with connection terminals 41 on which the first Ni-based plating layer 46 is not formed is used in the above step shown in FIG. 17. Additionally, instead of forming the second Ni-based plating layer 47 in FIG. 21, the surface-roughened layer 43 is provided on the second bottom surface 41b of each connection terminal 41 and on the portion 41c1 of the side surface 41c of the connection terminal 41 exposed from a corresponding recess 33.

When the circuit module 2 shown in FIG. 7 is produced and then the soldered circuit module 102 shown in FIG. 13 is produced, a substrate provided with connection terminals 41 on which the first Ni-based plating layer 46 is not formed is used in the above step shown in FIG. 17. Additionally, instead of forming the second Ni-based plating layer 47 in FIG. 21, the OSP-treated layer 44 is provided on the second bottom surface 41b of each connection terminal 41 and on the portion 41c1 of the side surface 41c of the connection terminal 41 exposed from a corresponding recess 33.

When the circuit module 3 shown in FIG. 8 is produced and then the soldered circuit module 103 shown in FIG. 14 is produced, a substrate provided with connection terminals 41 on which the first Ni-based plating layer 46 is not formed is used in the above step shown in FIG. 17. Additionally, in FIG. 21, the Ni-based plating layer 45 shown in FIG. 8 is formed on the second bottom surface 41b of each connection terminal 41 and on the portion 41c1 of the side surface 41c of the connection terminal 41 exposed from a corresponding recess 33.

When the circuit module 4 shown in FIG. 9 is produced and then the soldered circuit module 104 shown in FIG. 15 is produced, the surface-roughened layer 43 is provided on the second bottom surface 41b of each connection terminal 41 instead of forming the second Ni-based plating layer 47 in the above step shown in FIG. 21. In this case, the first Ni-based plating layer 46 shown in FIG. 17 serves as a layer regarded as the Ni-based plating layer 45.

Hereinafter, a sixth embodiment, which is yet another embodiment of the circuit module and soldered circuit module of the present disclosure, will be described.

In the circuit module of the sixth embodiment described below, a solder wettability improving layer is further provided on the surfaces of the recesses.

FIG. 23 is an enlarged schematic view showing the structure around a connection terminal in a circuit module of a sixth embodiment.

In a circuit module 6 of the sixth embodiment, the solder wettability improving layer 42 is the Ni-based plating layer 45. In FIG. 23, the Ni-based plating layer 45 is provided on the second bottom surface 41b of the connection terminal 41 and on the entire portion 41c1 of the side surface 41c of the connection terminal 41 exposed from the recess 33. Additionally, the Ni-based plating layer 45 serving as the solder wettability improving layer 42 is provided also on a portion of the bottom surface 33c of the recess 33 constituting the surface of the recess 33.

The same configuration as the circuit module of the third embodiment can be employed, except that the Ni-based plating layer serving as the solder wettability improving layer is further provided on the bottom surface of the recess.

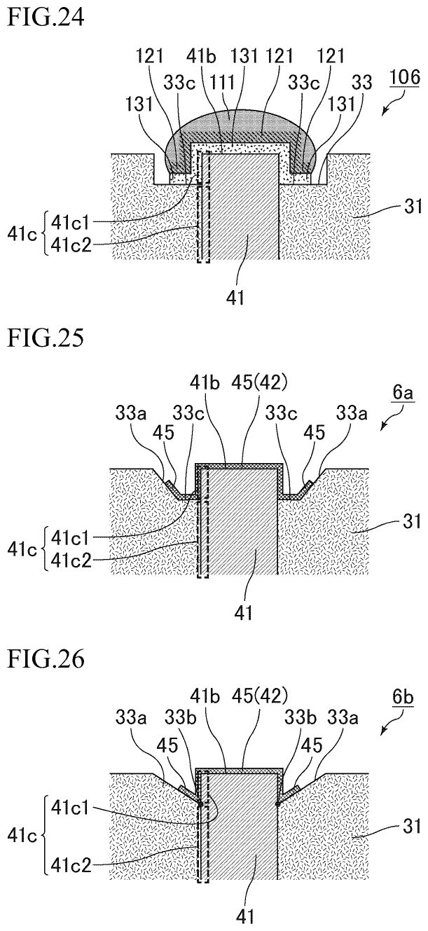

FIG. 24 is an enlarged schematic view showing the structure around a connection terminal in a soldered circuit module of the sixth embodiment.

A soldered circuit module 106 of the sixth embodiment can be obtained by bonding the solder bumps 111 to the connection terminals 41 of the circuit module 6 of the sixth embodiment shown in FIG. 23.

In the circuit module 6 of the sixth embodiment, the Ni-based plating layer 45 serving as the solder wettability improving layer 42 is also provided on a portion of the bottom surface 33c of each recess 33 constituting the surface of the recess 33, so that the solder bump wets and spreads on the surface of the recess 33.

In the soldered circuit module 106, the Ni-plating-derived layer 131 is formed between each connection terminal 41 and a corresponding intermetallic compound layer 121. Additionally, the Ni-plating-derived layer 131 is formed on a portion of the bottom surface 33c constituting the surface of the recess 33.

Moreover, the intermetallic compound layer 121 is formed on the surface of the Ni-plating-derived layer 131 on a portion of the bottom surface 33c of the recess 33 constituting the surface of the recess 33.

The Ni-plating-derived layer 131 contains Ni. The Ni-plating-derived layer 131 may be a layer derived from the Ni-based plating layer 45 in FIG. 23.

Regarding the shape of the recesses, the side surface of each recess opposite to a corresponding connection terminal may have a tapered shape such that the depth of the recess decreases as the distance from the connection terminal 41 increases.

FIG. 25 is an enlarged schematic view showing the structure around a connection terminal in another example circuit module of the sixth embodiment.

In a circuit module 6a shown in FIG. 25, a side surface 33a of each recess 33 opposite to a corresponding connection terminal 41 has a tapered shape such that the depth of the recess 33 decreases as the distance from the connection terminal 41 increases.

The surface of a recess 33 includes the bottom surface 33c of the recess 33 and the side surface 33a of the recess 33. The Ni-based plating layer 45 serving as the solder wettability improving layer 42 is provided on the entire bottom surface 33c of the recess 33, and also on a portion of the side surface 33a of the recess 33 continuously from the bottom surface 33c of the recess 33.

FIG. 26 is an enlarged schematic view showing the structure around a connection terminal in another example circuit module of the sixth embodiment.

In a circuit module 6b shown in FIG. 26, the side surface 33a of each recess 33 opposite to a corresponding connection terminal 41 has a tapered shape such that, starting from a contact point 33b between the recess 33 of the resin layer and the connection terminal 41, the depth of the recess 33 decreases as the distance from the connection terminal 41 increases.

The recess 33 is also considered to have only the side surface 33a without the bottom surface 33c.

The Ni-based plating layer 45 serving as the solder wettability improving layer 42 is also provided on a portion of the side surface 33a of the recess 33, starting from the contact point 33b between the recess 33 of the resin layer and the connection terminal 41.

Soldered circuit modules may be obtained by bonding solder bumps to the connection terminals of the circuit module 6a shown in FIG. 25 and the circuit module 6b shown in FIG. 26, e.g., using a Ni-plating-derived layer and an intermetallic compound layer will be formed on the surface of each recess at positions corresponding to the position of the Ni-based plating layer.

Hereinafter, a seventh embodiment, which is yet another embodiment of the circuit module and soldered circuit module of the present disclosure, will be described.

The following circuit module of the seventh embodiment corresponds to an embodiment in which the solder wettability improving layer is further provided on the surface of each recess in the circuit module of the fifth embodiment.

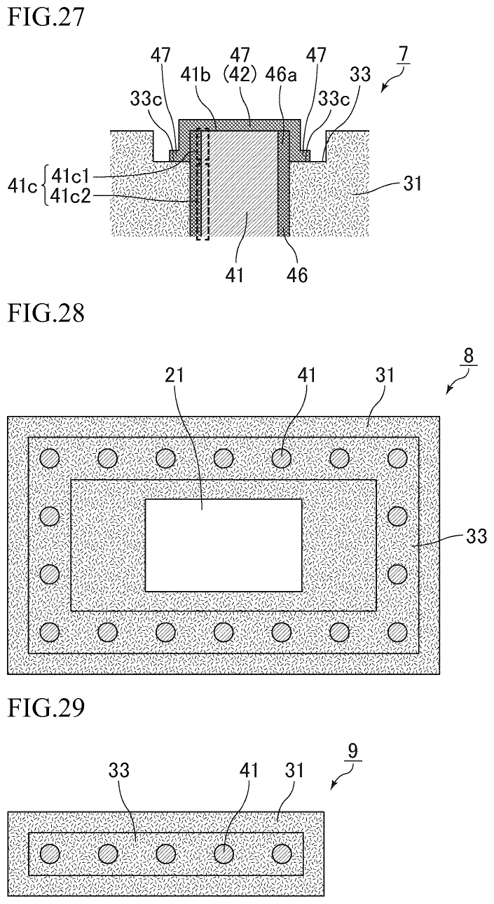

FIG. 27 is an enlarged schematic view showing the structure around a connection terminal in the circuit module of the seventh embodiment.

In a circuit module 7 of the seventh embodiment, the first Ni-based plating layer 46 is provided on the entire side surface 41c of each connection terminal 41. A portion of the first Ni-based plating layer 46 is exposed from a corresponding recess 33. Additionally, the second Ni-based plating layer 47 serving as the solder wettability improving layer 42 is provided on the second bottom surface 41b of the connection terminal 41 and on the portion 46a of the first Ni-based plating layer 46 exposed from the recess 33. The second Ni-based plating layer 47 serving as the solder wettability improving layer 42 is also provided on a portion of the bottom surface 33c of the recess 33 constituting the surface of the recess 33.

The same configuration as the circuit module of the fifth embodiment can be employed, except that the second Ni-based plating layer serving as the solder wettability improving layer is provided also on the bottom surface of the recess.

A soldered circuit module may be obtained by bonding solder bumps to the connection terminals in the circuit module 7 shown in FIG. 27, e.g., using a Ni-plating-derived layer and an intermetallic compound layer will be formed on the surface of each recess at positions corresponding to the position of the second Ni-based plating layer.

Hereinafter, a modified example of the circuit module of the present disclosure is described in which a single recess surrounds a plurality of connection terminals.

FIG. 28 is a plan view of a first modification of the circuit module of the present disclosure, as seen from the surface provided with a resin layer and connection terminals.

In a circuit module 8, a recess 33 has a frame shape. A single frame-shaped recess 33 is provided to surround a plurality of connection terminals 41. In the circuit module 8, the single frame-shaped recess 33 is provided to surround all the connection terminals 41.

FIG. 29 is a plan view of a second modification of the circuit module of the present disclosure, as seen from the surface provided with a resin layer and connection terminals.

In a circuit module 9, a recess 33 has a linear shape. A single linear-shaped recess 33 is provided to surround a plurality of connection terminals 41. In the circuit module 9, the single linear-shaped recess 33 is provided to surround all the connection terminals 41.

### EXAMPLES

Hereinafter, an Example of evaluating the bonding strength between solder and connection terminals in the soldered circuit module of the present disclosure will be described. The present disclosure is not limited to the Example. The following Example and Comparative Examples are provided in order to highlight characteristics of one or more embodiments, but it will be understood that the Example and Comparative Examples are not to be construed as limiting the scope of the embodiments, nor are the Comparative Examples to be construed as being outside the scope of the embodiments. Further, it will be understood that the embodiments are not limited to the particular details described in the Example and Comparative Examples.

### Example 1

A circuit module of Example 1 was prepared in which a NiAu plating layer serving as a solder wettability improving layer was provided on the second bottom surface of each connection terminal and on a portion of the side surface of the connection terminal exposed from a corresponding recess. In other words, a circuit module having a configuration in which the Ni-based plating layer 45 shown in FIG. 8 was a NiAu plating layer was prepared. Solder was bonded to the connection terminals of the circuit module of Example 1 to obtain a soldered circuit module of Example 1.

### Comparative Example 1

A circuit module of Comparative Example 1 was prepared by the same procedure as that for the circuit module of Example 1, except that no recess was formed in regions surrounding the second bottom surface of each connection terminal on the surface of the resin layer, and a NiAu plating layer serving as a solder wettability improving layer was provided only on the second bottom surface of each connection terminal. As in Example 1, solder was bonded to the connection terminals of the circuit module of Comparative Example 1 to obtain a soldered circuit module of Comparative Example 1.

### Comparative Example 2

A circuit module of Comparative Example 2 was prepared by the same procedure as that for the circuit module of Example 1, except that no solder wettability improving layer was provided either on the second bottom surface of each connection terminal or on the portion of the side surface of the connection terminal exposed from a corresponding recess. As in Example 1, solder was bonded to the connection terminals of the circuit module of Comparative Example 2 to obtain a soldered circuit module of Comparative Example 2.

### Evaluation of Bonding Strength

A High Speed Ball Shear Test was performed on the soldered circuit module of Example 1 and on the soldered circuit modules of Comparative Example 1 and Comparative Example 2. The High Speed Ball Shear Test is a test for evaluating the bonding strength between solder and an electrode by applying shear stress between the solder and the electrode using a shear tool. In this test, shear stress was applied between the solder and the connection terminals to evaluate the bonding strength between the solder and the connection terminals. As a result, the soldered circuit module of Example 1 exhibited a bonding strength between the solder and the connection terminals that was approximately twice as high as that of Comparative Example 1 or Comparative Example 2.

### The Following Matters Are Disclosed Herein.

<1>

A Circuit Module, Including:
a substrate having a first main surface and a second main surface;
a resin layer disposed on the first main surface of the substrate; and
a connection terminal penetrating the resin layer in a thickness direction of the resin layer,
the connection terminal including:
   a first bottom surface located adjacent to the substrate;
   a second bottom surface opposite to the first bottom surface; and
   a side surface,
wherein
the second bottom surface is exposed from the resin layer,
a recess that is recessed toward the first main surface of the substrate is formed in a region of a surface of the resin layer surrounding the second bottom surface of the connection terminal,
a portion of the side surface of the connection terminal is exposed from the resin layer in the recess, and
a solder wettability improving layer is provided on the second bottom surface of the connection terminal and on the portion of the side surface of the connection terminal exposed from the recess.
   <2>

The circuit module according to <1>,
wherein the solder wettability improving layer is a surface-roughened layer or an OSP-treated layer.
   <3>

The circuit module according to <1>,
wherein the solder wettability improving layer is a plating layer.
   <4>

The circuit module according to <3>,
wherein the solder wettability improving layer is a NiAu plating layer or a NiPdAu plating layer.
   <5>

The circuit module according to <1>,
wherein a surface-roughened layer or an OSP-treated layer is provided as the solder wettability improving layer on the second bottom surface of the connection terminal,
a NiAu plating layer is provided on the entire side surface of the connection terminal, and
a portion of the NiAu plating layer exposed from the recess serves as the solder wettability improving layer.
   <6>

The circuit module according to <1>,
wherein a first NiAu plating layer is provided on the entire side surface of the connection terminal,
a second NiAu plating layer or a NiPdAu plating layer, serving as the solder wettability improving layer, is provided on the second bottom surface of the connection terminal and on the portion of the side surface of the connection terminal exposed from the recess, and
in the portion of the side surface of the connection terminal exposed from the recess, the first NiAu plating layer is covered with the second NiAu plating layer or the NiPdAu plating layer.
   <7>

The circuit module according to any one of <1>to <6>,
wherein the solder wettability improving layer is further provided on a surface of the recess.
   <8>

A soldered circuit module, comprising:
a substrate having a first main surface and a second main surface;
a resin layer disposed on the first main surface of the substrate;
a connection terminal penetrating the resin layer in a thickness direction of the resin layer; and
a solder bump bonded to the connection terminal via an intermetallic compound layer,
the connection terminal including:
   a first bottom surface located adjacent to the substrate;
   a second bottom surface opposite to the first bottom surface; and
   a side surface,
wherein
the second bottom surface is not covered with the resin layer,
a recess that is recessed toward the first main surface of the substrate is formed in a region of a surface of the resin layer surrounding the second bottom surface of the connection terminal,
a portion of the side surface of the connection terminal is exposed from the resin layer in the recess,
the solder bump is provided to cover the second bottom surface of the connection terminal and at least part of the portion of the side surface of the connection terminal exposed from the recess, and
the intermetallic compound layer is present between the connection terminal and the solder bump and covers the second bottom surface of the connection terminal and at least part of the portion of the side surface of the connection terminal exposed from the recess.
   <9>

The soldered circuit module according to <8>,
wherein the solder bump and the intermetallic compound layer extend to the surface of the resin layer recessed in the recess.
   <10>

The soldered circuit module according to <8>or <9>,
wherein a Ni-plating-derived layer is present between the connection terminal and the intermetallic compound layer.

### REFERENCE SIGNS LIST

1, 2, 3, 4, 5, 6, 6a, 6b, 7, 8, 9 circuit module
11 substrate
11a first main surface of substrate
11b second main surface of substrate
12 electrode
13 insulating layer
14 patterned conductor
15 via conductor
16 connection member
21 electronic component
31, 32 resin layer
33 recess
33a side surface of recess
33b contact point between recess of resin layer and connection terminal
33c bottom surface of recess
41, 41E connection terminal
41a first bottom surface
41b second bottom surface
41c side surface
41c1 portion of side surface exposed from recess
41c2 portion of side surface not exposed from recess
42 solder wettability improving layer
43 surface-roughened layer
44 OSP-treated layer
45 Ni-based plating layer
45a portion of Ni-based plating layer exposed from recess
46 first Ni-based plating layer
46a portion of first Ni-based plating layer exposed from recess
47 second Ni-based plating layer
51 laser-irradiation trace
52 laser-unirradiated portion
101, 102, 103, 104, 105, 106 soldered circuit module
111 solder bump
121 intermetallic compound layer
131 Ni-plating-derived layer

1. A circuit module, comprising:
a substrate having a first main surface and a second main surface;
a resin layer disposed on the first main surface of the substrate; and
a connection terminal extending through the resin layer in a thickness direction of the resin layer,
the connection terminal including:
a first end surface adjacent to the substrate;
a second end surface opposite to the first end surface; and
a side surface extending between the first and second end surfaces,
wherein
the second end surface is exposed from the resin layer,
the resin layer includes a recess that extends toward the first main surface of the substrate and surrounds the second end surface of the connection terminal,
a portion of the side surface of the connection terminal is exposed from the resin layer within the recess, and
a solder wettability improving layer is disposed on the second end surface of the connection terminal and on the portion of the side surface of the connection terminal exposed within the recess.

2. The circuit module according to claim 1,
wherein the solder wettability improving layer is a surface-roughened layer or an OSP-treated layer.

3. The circuit module according to claim 1,
wherein the solder wettability improving layer is a plating layer.

4. The circuit module according to claim 3,
wherein the solder wettability improving layer is a NiAu plating layer or a NiPdAu plating layer.

5. The circuit module according to claim 1,
wherein a NiAu plating layer is provided on the entire side surface of the connection terminal.

6. The circuit module according to claim 5,
wherein a portion of the NiAu plating layer exposed from the recess serves as the solder wettability improving layer.

7. The circuit module according to claim 5,
wherein the NiAu plating layer is a first NiAu plating layer,
the circuit module further includes a second NiAu plating layer or a NiPdAu plating layer, serving as the solder wettability improving layer, provided at least on the portion of the side surface of the connection terminal exposed from the recess, and
in the portion of the side surface of the connection terminal exposed from the recess, the first NiAu plating layer is covered with the second NiAu plating layer or the NiPdAu plating layer.

8. The circuit module according to claim 1,
wherein a surface-roughened layer or an OSP-treated layer is provided as the solder wettability improving layer on the second end surface of the connection terminal,
a NiAu plating layer is provided on the entire side surface of the connection terminal, and
a portion of the NiAu plating layer exposed from the recess serves as the solder wettability improving layer.

9. The circuit module according to claim 1,
wherein a first NiAu plating layer is provided on the entire side surface of the connection terminal,
a second NiAu plating layer or a NiPdAu plating layer, serving as the solder wettability improving layer, is provided on the second end surface of the connection terminal and on the portion of the side surface of the connection terminal exposed from the recess, and
in the portion of the side surface of the connection terminal exposed from the recess, the first NiAu plating layer is covered with the second NiAu plating layer or the NiPdAu plating layer.

10. The circuit module according to claim 1,
wherein the solder wettability improving layer is further provided on a surface of the recess.

11. The circuit module according to claim 1,
wherein a side surface of the recess opposite to the connection terminal has a tapered shape such that a depth of the recess decreases as a distance from the connection terminal increases.

12. The circuit module according to claim 1,
wherein a laser-irradiation trace is present on at least part of the second end surface of the connection terminal.

13. The circuit module according to claim 1,
wherein the single recess surrounds a plurality of the connection terminals.

14. A soldered circuit module, comprising:
a substrate having a first main surface and a second main surface;
a resin layer disposed on the first main surface of the substrate;
a connection terminal extending through the resin layer in a thickness direction of the resin layer; and
a solder bump bonded to the connection terminal via an intermetallic compound layer,
the connection terminal including:
a first end surface adjacent to the substrate;
a second end surface opposite to the first end surface; and
a side surface extending between the first and second end surfaces,
wherein the second end surface is exposed from the resin layer,
the resin layer includes a recess that extends toward the first main surface of the substrate and surrounds the second end surface of the connection terminal,
a portion of the side surface of the connection terminal is exposed from the resin layer within the recess,
the solder bump covers the second end surface of the connection terminal and at least part of the portion of the side surface of the connection terminal exposed within the recess, and
the intermetallic compound layer is between the connection terminal and the solder bump and covers the second end surface of the connection terminal and at least part of the portion of the side surface of the connection terminal exposed within the recess.

15. The soldered circuit module according to claim 14,
wherein the solder bump and the intermetallic compound layer extend to the surface of the resin layer recessed in the recess.

16. The soldered circuit module according to claim 14,
wherein a Ni-plating-derived layer is present between the connection terminal and the intermetallic compound layer.

17. A soldered circuit assembly comprising:
a circuit module including a substrate, a resin layer on the substrate, and a connection terminal extending through the resin layer, wherein a portion of a side surface of the connection terminal is exposed from the resin layer via a recess formed in the resin layer;
a solder bump bonded to an end surface of the connection terminal and the exposed portion of the side surface; and
an intermetallic compound layer disposed at an interface between the connection terminal and the solder bump,
wherein the intermetallic compound layer is vertically offset from a non-recessed outer surface of the resin layer.

18. The soldered circuit assembly according to claim 17, wherein the solder bump and the intermetallic compound layer extend to a bottom of the recess.
